(19) United States
(12) Patent Application Publication
(10) Pub. No.: US 2025/0174503 A1
(43) Pub. Date: May 29, 2025

(54) SEMICONDUCTOR DEVICE AND ELECTRIC POWER CONVERSION DEVICE

(71) Applicant: Minebea Power Semiconductor Device Inc., Ibaraki (JP)

(72) Inventors: Norio NAKAZATO, Tokyo (JP); Hitoshi NISHIMORI, Tokyo (JP); Takayuki KUSHIMA, Hitachi-shi (JP); Kouji SASAKI, Hitachi-shi (JP)

(21) Appl. No.: 18/842,851

(22) PCT Filed: Nov. 24, 2022
(86) PCT No.: PCT/JP2022/043330

§ 371 Date: Aug. 30, 2024

(30) Foreign Application Priority Data
Mar. 23, 2022 (JP) 2022-046809

(51) Int. Cl. H01L 23/13; H01L 21/48; H01L 23/00; H01L 23/14; H01L 23/498; H10D 80/20

(52) U.S. Cl. CPC H01L 23/13; H01L 24/29; H01L 24/32; H10D 80/231; H10D 80/251; H01L 21/4803; H01L 23/142; H01L 23/49822; H01L 23/49833; H01L 24/27; H01L 24/83; H01L 2224/2732; H01L 2224/29005; H01L 2224/29017; H01L 2224/29018; H01L 2224/29339; H01L 2224/29344; H01L 2224/32225; H01L 2224/8384; H01L 2924/30101

(57) ABSTRACT

Thermal resistance of a sintered metal joining section is reduced to cope with an increase in the area of a chip size and layer thinning of the semiconductor chip. A sintered metal layer joins the semiconductor chip to a wiring layer and the wiring layer has a trench extending from the semiconductor chip mounting region where the semiconductor chip is mounted to the outside of the semiconductor chip mounting region. The sintered metal layer is formed in the trench and to the outside of the upper end of the trench and in the trench formed to the outside of the semiconductor chip mounting region. The depth of the trench differs between the trench in the vicinity of the center of the semiconductor chip mounting region and the trench in the vicinity of the end portion of the semiconductor chip mounting region.

### TECHNICAL FIELD

The present invention relates to a semiconductor device and an electric power conversion device.

### BACKGROUND ART

As an electric power conversion device that carries out electric power conversion or control of electric vehicles, railway vehicles, power generation systems, and the like, semiconductor devices using IBGT (Insulated Gate Bipolar Transistor), MOSFET (Metal-Oxide-Semiconductor Field-Effect Transistor) or the like have been used. Since the temperature of a semiconductor chip increases due to self heat generation when a semiconductor device is in operation, a problem to be overcome is to ensure the reliability against a thermal load. Techniques described, for example, in Patent Literatures 1 to 3 are known as a technique developed to satisfy the aforesaid requirement for improving heat release properties.

### CITATION LIST

### Patent Literature

Patent Literature 1: Japanese Unexamined Patent Application Publication No. 2017-103180
Patent Literature 2: International Publication WO 2017/002793
Patent Literature 3: Japanese Unexamined Patent Application Publication No. 2017-092168

### SUMMARY OF INVENTION

### Technical Problem

The technique described in the aforesaid Patent Literature 1 is a method of providing a copper paste for pressurization-free bonding capable of achieving a sufficient bonding strength even if it is used for bonding members different in coefficient of thermal expansion without pressurization. The paste contains metal particles and a dispersion medium. The metal particles contain submicro copper particles having a volume-average particle size of 0.01 μm or more and 0.8 μm or less and micro copper particles having a volume-average particle size of 2.0 μm or more and 50 μm or less. The dispersion medium contains a solvent having a boiling point of 300° C. or more. The content of the solvent having a boiling point of 300° C. or more is 2 mass % or more based on the total mass of the copper paste for pressurization-free bonding. The aforesaid technique is for suppressing microcracks by ensuring the movement/deformation of the copper particles during a solvent drying step to decrease a void ratio of a porous structure which is a cause for insufficient strength or increased thermal resistance of a bonded part. The aforesaid technique is effective when the semiconductor chip has a size of several mm square, but pressurization under a low pressure is indispensable when the chip size is 10 mm square or the like. Since the coating thickness increases for the measure against coating unevenness and an outgas amount from the solvent increases, low-pressure pressurization the floating of the chip should be suppressed by. A flow path of an outgas from a coating layer at the center of the chip is formed and this makes it difficult to reduce the thermal resistance.

The technique described in the aforesaid Patent Literatures 2 to 3 is to place a recess portion on an electrode surface to be bonded with a semiconductor chip to prevent, when a coating thickness of a sintered metal paste is increased, the paste from protruding from the outer edge of the chip and becoming an un-bonded and separable foreign matter and thereby improve the bonding strength by the anchor effect of the recess portion. An outgas from a solvent is communicated in the thick coating layer to be a flow path and is released to the outside, making it difficult to reduce the thermal resistance of the chip having an increased area. In addition, with a further increase in the area of the chip, the chip has a thickness of 100 μm or less so that pressurization under low pressure is indispensable.

The present invention has been made in consideration of the aforesaid problem and the object is to provide a technique capable of reducing the thermal resistance of a sintered metal bonding portion to cope with an increase in the area of a chip size and layer thinning of a semiconductor chip.

### Solution to Problem

The present invention is constituted as follows to overcome the aforesaid problem.

Provided is a technique having a wiring layer, a semiconductor chip, a sintered metal layer that bonds the wiring layer to the semiconductor chip; the wiring layer has trenches extending from a semiconductor chip mounting region in which the semiconductor chip is mounted to an outside of the semiconductor chip mounting region; the sintered metal layer is formed in the trenches and on the outside of an upper end of the trenches in the semiconductor chip mounting region; the sintered metal layer is also formed in the trenches formed on the outside of the semiconductor chip mounting region; and the trenches are different in depth between a vicinity of a center of the semiconductor chip mounting region and a vicinity of an end portion of the semiconductor chip mounting region.

### Advantageous Effects of Invention

According to the present invention, it is possible to provide a technique capable of reducing the thermal resistance of a sintered metal bonding portion to cope with an increase in the area of a chip size and layer thinning of a semiconductor chip.

### BRIEF DESCRIPTION OF DRAWINGS

FIG. 1 is a schematic cross-sectional view showing the main portion of a semiconductor device according to a first embodiment.

FIG. 2a is a top view showing the main portion of the semiconductor device according to the first embodiment.

FIG. 2b is a cross-sectional view of the main portion of the semiconductor device according to the first embodiment, which is taken along the line B-B.

FIG. 2c is a cross-sectional view of the main portion of the semiconductor device according to the first embodiment, which is taken along the line C-C.

FIG. 2d is a top view for describing a mounting region of the semiconductor chip 1 shown in FIG. 2a.

FIG. 3 is an enlarged cross-sectional view of the portion D of the main portion of the semiconductor device according to the first embodiment.

FIG. 4 is an enlarged cross-sectional view of the portion D of the main portion of the semiconductor device according to the second embodiment.

FIG. 5 is a cross-sectional view of the main portion of a semiconductor device according to a modification of the first embodiment, which is taken along the line B-B.

FIG. 6a is a cross-sectional view of a thermal conduction analysis model according to the first embodiment.

FIG. 6b is an enlarged cross-sectional view of the portion E of the thermal conduction analysis model according to the first embodiment.

FIG. 6c is a cross-sectional temperature distribution diagram according to the first embodiment.

FIG. 7 is a comparison diagram of thermal resistance of thermal conduction analysis results according to the first embodiment.

FIG. 8 is a circuit diagram showing an embodiment of an electric power conversion device using the semiconductor device of the first embodiment or the second embodiment.

### DESCRIPTION OF EMBODIMENTS

Preferred modes for carrying out the present invention will hereinafter be described referring to drawings as needed. The present invention is however not limited to the embodiments shown herein and can be used in combination with another embodiment or can be improved without changing the gist of the present invention. In the following description, the same components may be identified by the same reference numeral and an overlapping description may be omitted. To make a description clearer, a drawing may be a schematic one compared with that of an actual aspect, but it is only an example and does not limit the interpretation of the present invention.

### First Embodiment

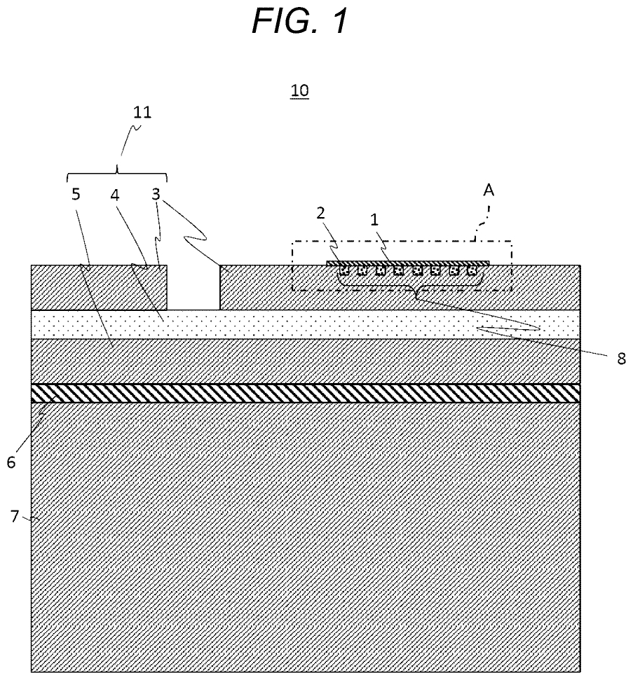

FIG. 1 is a schematic cross-sectional view showing the main portion of a semiconductor device according to a first embodiment of the present invention. As shown in FIG. 1, a semiconductor device 10 is a semiconductor device used for an electric power conversion device that carries out the electric power conversion or control of electric vehicles, railway vehicles, power generation systems, and the like and it has a stack structure in which a semiconductor chip 1, a substrate 11, and a base 7 are bonded one after another. Although not shown in FIG. 1, a plurality of substrates 11 is sometimes mounted on one base 7.

The semiconductor chip 1 is a power transistor such as IGBT (Insulated Gate Bipolar Transistor) or MOSFET (metal-oxide-semiconductor field-effect transistor), or a diode and for example, silicon Si, silicon carbide SiC, gallium nitride GaN, or the like is used for it.

The substrate 11 is made of a first metal layer (also called “wiring layer”) 3, an insulation layer 4, and a second metal layer 5. The first metal layer 3 has a function of a wiring layer as an electrode pattern for circuit and as a material of it, copper (Cu), a copper (Cu) alloy, aluminum (Al), an aluminum (Al) alloy, or the like having good electrical conductivity and thermal conductivity is desired. The second metal layer 5 has a thermal diffusion plate function and as a material of it, for example, Cu, a Cu alloy, Al, an Al alloy, or the like is used similarly. The insulation layer 4 desirably has a high insulation property and thermal conductivity and for example, ceramics such as aluminum nitride, aluminum oxide, or silicon nitride is used. The base 7 has a function as a face for releasing heat to the outside and desirably has high rigidity and thermal conductivity. For it, Cu, a Cu alloy, Al, an Al alloy, a composite material (AlSiC) of aluminum and silicon carbide, a composite material (MgSiC) of magnesium and silicon carbide, and the like are used.

The semiconductor device 10 has, between the semiconductor chip 1 and the first metal layer 3 of the substrate 11, a chip bonding layer (also called “sintered metal layer”) 2 and it has, between the substrate 11 and the base 7, a base bonding layer 6. For the chip bonding layer 2, sinter bonding materials and the like having high thermal conductivity and high thermal resistance, such as copper (Cu) nano particles and silver (Ag) nano particles, are used. For the base bonding layer 6, a material having high thermal conductivity, for example, a solder composed mainly of lead Pb or Tin Sn is used.

The first metal layer 3 constitutes a part of an electrical circuit and is electrically connected to the semiconductor chip 1 or a terminal to be electrically connected to the outside. The semiconductor device 10 is housed in a resin case or the like having a high insulation property and the inside of this resin case is sealed with a resin or a gel.

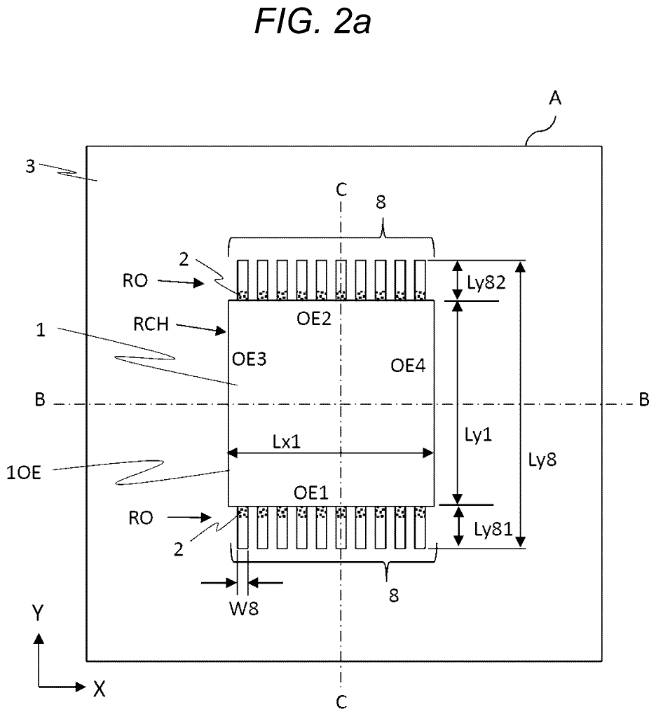

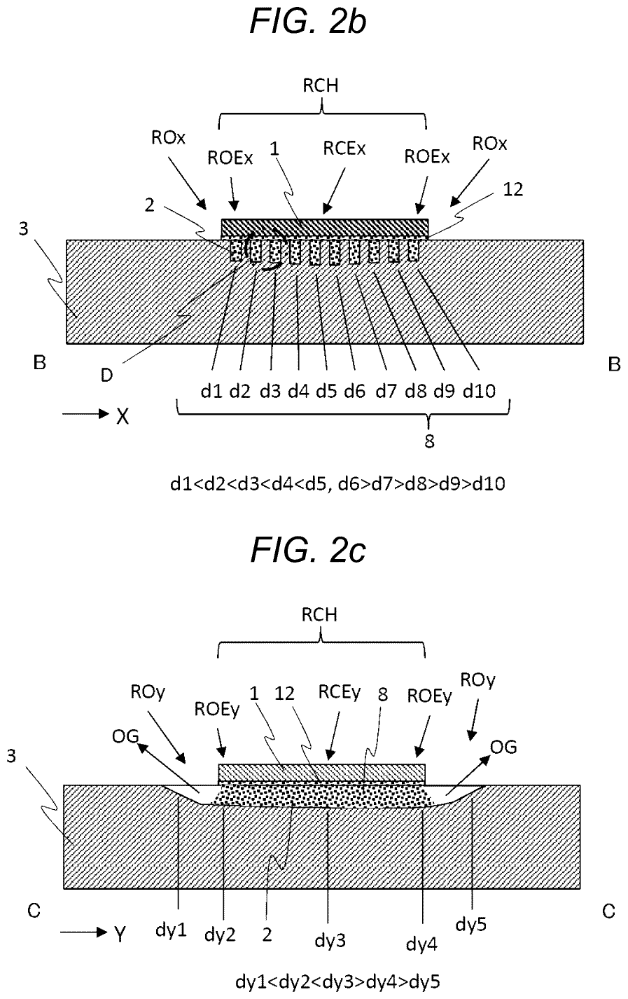

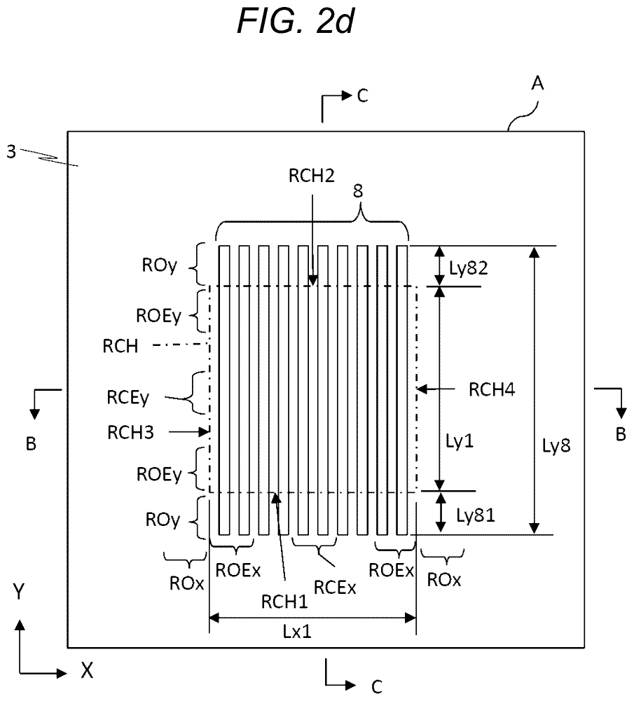

FIG. 2a is a top view showing the main portion of the semiconductor device according to the first embodiment of the present invention. FIG. 2b is a cross-sectional view taken along the line B-B shown in FIG. 2a and FIG. 2c is a cross-sectional view taken along the line C-C shown in FIG. 2a. FIG. 2d is a top view that describes the semiconductor chip mounting region RCH of FIG. 2a.

As shown in FIG. 1, FIG. 2a, FIG. 2b, and FIG. 2c, the substrate 11 has, on the surface side of the first metal layer 3, a bonding region (also called “mounting region RCH of the semiconductor chip 1 or a semiconductor chip mounting region RCH”) to which the semiconductor chip 1 is bonded. The first metal layer 3 has, in the bonding region (mounting region RCH) on the surface side thereof, a plurality of trenches 8 formed by mechanical processing, press processing, etching processing, or the like. As shown in FIG. 2a, the trenches 8 are formed to protrude its length Ly8 from an outer edge 10E of the semiconductor chip 1. In other words, the first metal layer 3, which is a wiring layer of the substrate 11, has a plurality of trenches 8 extending from the mounting region RCH of the semiconductor chip 1 to the outside RO of the mounting region RCH of the semiconductor chip 1. In the mounting region RCH of the semiconductor chip 1, the trench 8 has the chip bonding layer 2 and a thin bonding layer 12, which are sintered metal layers, in the trench 8 and also on the outside of the upper end of the trench 8 (refer to FIG. 2b and FIG. 2c). The trench 8 formed on the outside RO of the mounting region RCH of the semiconductor chip 1 also has the chip bonding layer 2, which is a sintered metal layer.

As shown in FIG. 2a, the semiconductor chip 1 has, in the top view thereof, a rectangular shape having four sides (OE1 to OE4). The outer edge 10E of the semiconductor chip 1 has a first side OE1 provided along a first direction X, a second side OE2 opposite to the first side OE1, a third side OE3 provided between the first side OE1 and the second side OE2, and a fourth side OE4 opposite to the third side OE3. The third side OE3 and the fourth side OE4 are provided along a second direction Y that intersects the first direction X. The mounting region RCH of the semiconductor chip 1 provided on the first metal layer 3 is, in the top view, a region similar to an inside rectangular region surrounded by the first side OE1 to the fourth side OE4 of the semiconductor chip 1.

The length of the first side OE1 and the second side OE2 is Lx1 and the length of the third side OE3 and the fourth side OE4 is Ly1. This means that a plurality of trenches 8 is provided, on the surface side of the first metal layer 3, parallel to the first direction X and these trenches 8 are each provided along the second direction Y. The length Ly8 of the trench 8 extending along the second direction Y is longer than the length Ly1 of the third side OE3 or the fourth side OE4 of the semiconductor chip 1 extending along the second direction Y (Ly8>Ly1). In the constitution example of the trench 8 shown in FIG. 2a, the length Ly8 of the trench 8 is the sum (Ly8=Ly1+Ly81+Ly82) of the length (Ly1) of the third side OE3 or the fourth side OE4 of the semiconductor chip 1, a protruding length (Ly81) from the first side OE1 of the semiconductor chip 1 on the lower side of the trench 8, and a protruding length (Ly82) from the second side OE2 of the semiconductor chip 1 on the upper side of the trench 8. In this example, Ly81 and Ly82 have the same length (Ly81=Ly82). It is to be noted that Ly81 has a length different from that of Ly82 (Ly81≠Ly82). The widths W8 of the plurality of trenches 8 extending along the first direction X are the same in this example. It is to be noted that the widths W8 of the plurality of trenches 8 extending along the first direction X may be different from each other.

The mounting region RCH of the semiconductor chip 1 will hereinafter be described referring to FIG. 2d. FIG. 2d corresponds to a simplified top view obtained by removing the semiconductor chip 1 and the chip bonding layer 2 from the top view of FIG. 2a. In FIG. 2d, the mounting region RCH of the semiconductor chip 1 is present in a rectangular region surrounded by a dashed line and has a first side RCH1 provided along the first direction X, a second side RCH2 opposite to the first side RCH1, a third side RCH3 provided between the first side RCH1 and the second side RCH2, and a fourth side RCH4 opposite to the third side RCH3. The third side RCH3 and the fourth side RCH4 are provided along the second direction Y that intersects the first direction X.

The mounting region RCH of the semiconductor chip 1 has a center-vicinity RCEx of the mounting region RCH and a pair of end-portion-vicinity ROExs, which pair is provided at the end portion on both sides of the mounting region RCH. The outside of the end-portion-vicinity ROExs of the mounting region RCH is indicated as ROx. No trench 8 is provided on the outside ROx.

The mounting region RCH of the semiconductor chip 1 has, in the second direction Y, a center-vicinity RCEy of the mounting region RCH and a pair of end-portion-vicinity ROEys, which pair is provided at the end portion on both sides of the mounting region RCH. The outside of the end-portion-vicinity ROEys of the mounting region RCH is indicated as ROy. The outside ROy has protruding portions (a portion of the protruding length Ly81 and a portion of the protruding length Ly82) of the trench 8.

The depth of the plurality of trenches 8 in the first direction X will be described referring to FIG. 2b. As shown in FIG. 2b, the trench 8 is formed on the surface side of the first metal layer 3 to differentiate the depth d of the trench 8 between the center-vicinity RCEx of the mounting region RCH of the semiconductor chip 1 and end-portion-vicinity ROEx of the mounting region RCH of the semiconductor chip 1. In FIG. 2b, ten trenches 8 are illustrated typically. The depths d1 and d10 of the trenches 8 provided in the end-portion-vicinity ROEx are shallower than the depths d5 and d6 of the trenches 8 provided in the center-vicinity RCEx (d1 and d10<d5 and d6). In this example, the trenches 8 are deep in the following order: d1<d2<d3<d4<d5 and d6>d7>d8>d9>d10. This means that the depths d1 and d10 of the trenches 8 provided in the end-portion-vicinity ROEx are shallow and the depths d5 and d6 of the trenches 8 provided in the center-vicinity RCEx are deeper than those of d1 and d10. The depth of the trenches 8 provided in the center-vicinity RCEx is the deepest and the depth of the trenches 8 is constituted to gradually decrease from the center-vicinity RCEx to the end-portion-vicinity ROEx. The depths d5 and d6 of the trench 8 provided in the center-vicinity RCEx may be the same (d5=d6) or alternately, the depths d5 and d6 may be different (d5≠d6).

FIG. 3 is an enlarged view of the portion D shown in FIG. 2b. As shown in FIG. 3, there are trenches 80 and 81 having a depth d2 and a depth d3 which are different from each other.

The depth of the trenches 8 in the second direction Y will be described referring to FIG. 2c. As shown in FIG. 2c, in any trench 8, the depth dy3 of the trench 8 is the deepest below the center portion of the semiconductor chip 1 (in other words, the center-vicinity RCEy of the mounting region RCH of the semiconductor chip 1) and the depths dy1 and dy5 of the trench 8 gradually become shallower from the depths dy2 and dy4 of the trench 8 at the outer edge portion of the semiconductor chip 1 (in other words, the end-portion-vicinity ROEy of the mounting region RCH of the semiconductor chip 1) to the outside of the semiconductor chip 1 (in other words, the outside ROy of the mounting region RCH of the semiconductor chip 1) (d3>(dy2 and dy4)>(dy1 and dy5)).

As shown in FIG. 2b and FIG. 2c, the remaining region of the first metal layer 3 having no trench 8 therein is a flat surface of the first metal layer 3 and the flat surface of the first metal layer 3 and the back surface of the semiconductor chip 1 are bonded by the thin bonding layer 12. The width W8 of the trenches 8 is, for example, 200 μm or less and the depth d (d1 to d10 and dy1 to dy5) of the trenches 8 is, for example, 200 μm or less. The thickness of the thin bonding layer 12 is, for example, around 20 μm.

The semiconductor device 10 of the first embodiment of the present invention is constituted as described above. In general, when a chip bonding layer is a sintered body containing a plurality of metal crystal grains, it has a porous structure and with an increase in size or density of pores, microcracks are likely to be formed during a bonding step for manufacture. When it is used in a high temperature environment such as 175° C. to 300° C., it has less bonding reliability and due to cutting of a thermal conduction route in the bonding layer, it has increased thermal resistance.

The chip bonding layer 2 and the thin bonding layer 12 are formed by dispersing metal nanoparticles, such as Ag nanoparticles, covered with an organic protection film in an organic component to obtain a sinter bonding material (also called as “bonding material paste”) in paste form, applying and supplying the resulting material between the first metal layer 3 and the back surface of the semiconductor chip 1 by screen printing or the like, heating the resulting material at a desired bonding temperature while applying a pressure thereto, and sintering and bonding a plurality of metal nanoparticles to each other. When copper oxide particles are used and an oxide film is removed to form nanoparticles, it is desired to use a sinter bonding material containing a reducing agent which can be evaporated at a bonding temperature (60° C.). A discharge path of an outgas generated in an evaporation step and sintering reaction step of the reducing agent is a cause of increasing pores.

In the semiconductor device 10 according to the first embodiment of the present invention, it is possible to reduce the size and density of the pores in the thin bonding layer 12 by releasing the extra portion of the bonding material paste to the trenches 8 under low-pressure pressurization and thereby forming the thin bonding layer 12 and making it easy to introduce the outgas OG, which is generated during the evaporation step and sintering reaction step of the reducing agent, into the outside ROy of the mounting region RCH of the semiconductor chip 1 through the trenches 8 (refer to FIG. 2c). This makes it possible to improve the bonding reliability at a high temperature environment such as 175° C. to 300° C. and reduce the thermal resistance in the bonding layers (2 and 12).

The formation method of the trenches 8 is preferably cutting processing, for example, with a diamond blade saw. When it is used, a sintered film is formed in the cutting mark formed on the side wall of the trenches 8 and this produces an anchor effect. This makes it possible to suppress interfacial separation of the chip bonding layer 2 formed in the trenches 8 and moreover, cope with an increase in chip size, that is, an increase in the area of the semiconductor chip 1.

By forming the trenches 8 to have a larger depth at a position below the center portion of the semiconductor chip 1 (the center-vicinity RCEx and RCEy of the mounting region RCH of the semiconductor chip 1), a housing amount of the extra bonding material paste can be ensured and at the same time, the stress to the semiconductor chip 1 when cooled from the sintering processing temperature 300° C. to normal temperature can be relaxed. In addition, the base 7 without warping can be provided for use.

### (Modification)

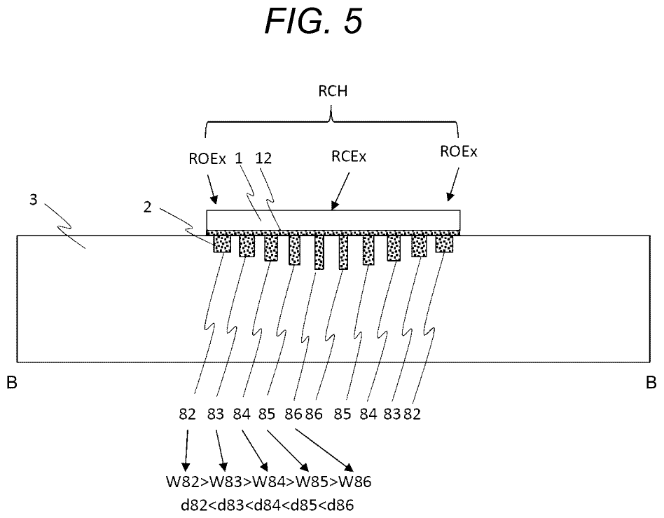

FIG. 5 is a cross-sectional view of the main portion of a semiconductor device of a modification of the first embodiment, which is taken along the line B-B. The depth d and the width W of a plurality of trenches 8 in the first direction X will be described referring to FIG. 5. In this modification, the depth d of the trenches 8 in the second direction Y is similar to that described using FIG. 2c.

In FIG. 5, in FIG. 2b, trenches 82, 83, 84, 85, and 86 obtained by gradually increasing the width W8 of a plurality of the trenches 8 from below (the center-vicinity RCEx) the center portion of the semiconductor chip 1 to the outer edge portion (the end-portion-vicinity ROEx) thereof are provided (width W82 of trench 82>width W83 of trench 83>width W84 of trench 84>width W85 of trench 85>width W86 of trench 86). On the other hand, trenches 82, 83, 84, 85, and 86 obtained by gradually decreasing the depth d of a plurality of the trenches 8 from below (the center-vicinity RCEx) of the center portion of the semiconductor chip 1 to the outer edge portion (the end-portion-vicinity ROEx) thereof are provided (depth d82 of trench 82>depth d83 of trench 83>depth d84 of trench 84>depth d85 of trench 85>depth d86 of trench 86).

Described specifically, in the modification, among the respective widths W of the plurality of the trenches (82, 83, 84, 85, and 86) in the first direction X, the width W of the trench of the center-vicinity RCEx (width W86 of the trench 86) is the narrowest and the width W of the trenches is gradually wider from the center-vicinity RCEx to the end-portion-vicinity ROEx. On the other hand, among the respective depths d of the plurality of the trenches (82, 83, 84, 85, and 86) in the first direction X, the depth of the trench of the center-vicinity RCEx is the deepest (depth d86 of the trench 86) and the depth d gradually decreases from the center-vicinity RCEx to the end-portion-vicinity ROEx. Further, with regards to the respective depths of the plurality trenches 8 in the second direction Y, the depth of the center-vicinity RCEx is the deepest and the depth d gradually decreases from the center-vicinity RCEx to the outside OE of the semiconductor chip mounting region RCH (refer to FIG. 2c).

This makes it possible to widen the area of the thin bonding layer 12 below the center portion of the semiconductor chip 1 (the center-vicinity RCEx) and thereby reducing the thermal resistance at a heat generation center. In addition, by increasing the depth of the trench 86, a discharge flow path of an outgas OG is ensured while keeping an extra amount of the bonding material paste. The outgas OG can be discharged in an arrow direction shown in FIG. 2c.

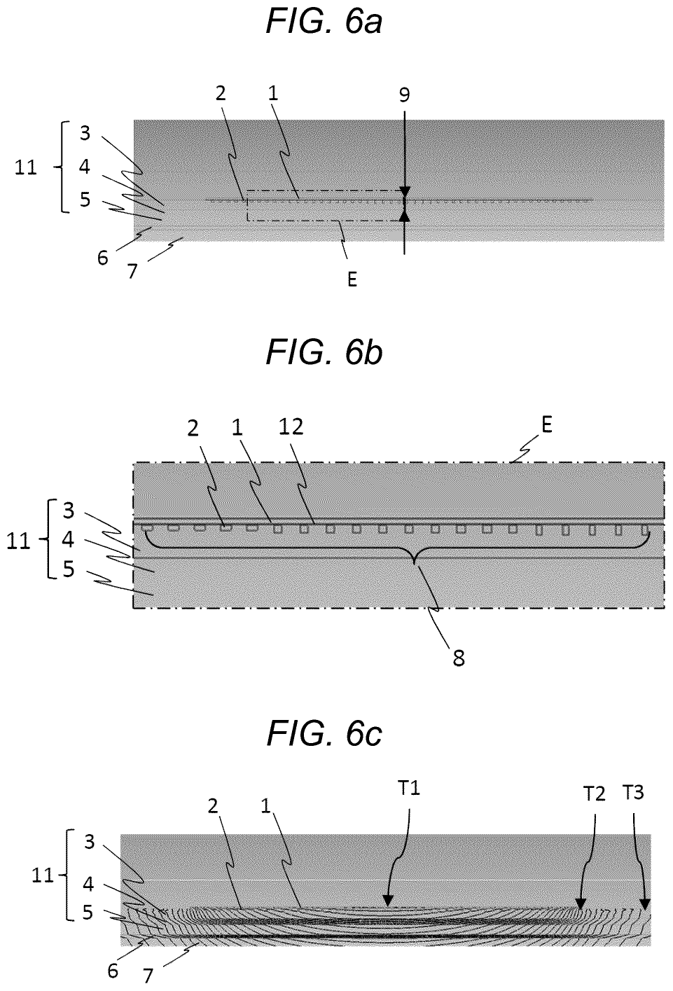

The effect of the present invention was verified using a thermal conduction analysis technique. FIG. 6a is a cross-sectional view of a thermal conduction analysis model corresponding to the main portion of the semiconductor device of FIG. 1. FIG. 6b is an enlarged view of the portion E shown in FIG. 6a. FIG. 6c is a cross-sectional temperature distribution diagram according to the first embodiment. With regards to a plurality of trenches 8, the trenches 8 each have a different width and depth from the center to the outer edge of a chip as described in FIG. 5. A semiconductor chip 1 was an Si chip, its chip size was 20 mm square, and its thickness was 0.08 mm. A thin bonding layer 12 had a thickness of 0.02 mm and a thermal conductivity of 200 W/mK. The bonding layer 2 with which the trench 8 was filled had a thermal conductivity corresponding to that of a solder and 23.4 W/mK. A fist metal layer 3 and a second metal layer had a size of 40 mm square, had a thickness of 0.5 mm, and a thermal conductivity of 396 W/mK corresponding to that of copper. An insulation layer 4 had a thickness of 0.32 mm and had a thermal conductivity of 80 W/mK corresponding to that of silicon nitride ceramics. A base bonding layer 6 had a thickness of 0.2 mm and had a thermal conductivity of 23.4 W/mk corresponding to that of a solder.

A base 7 had a thickness of 3 mm and had a thermal conductivity of 396 W/mK corresponding to that of copper. For the heat release surface of the base 7, a thermal conduction boundary condition (thermal conductivity of 30000 W/m2K) was set and the other surface was insulated. The temperature distribution obtained by causing uniform heat generation of the semiconductor chip 1 at 1 kW is shown in FIG. 6c. FIG. 6c shows an isotherm. In the example shown in FIG. 6c, the temperature T1 in the vicinity of the center of the semiconductor chip 1 falls in a temperature range of from about 61° C. to 56° C.; the temperature T2 in the vicinity of the end portion of the semiconductor chip 1 falls in a temperature range of from about 38° C. to 30° C.; and the temperature T3 in the vicinity of the end portion of the first metal layer 3 falls in a temperature range of from about 15° C. to 7° C. At the thermal resistance evaluation position 9 shown in FIG. 6a, thermal resistance of the bonding layer 12 was evaluated based on a temperature difference from the semiconductor chip 1 to the lower surface of the first metal layer 3.

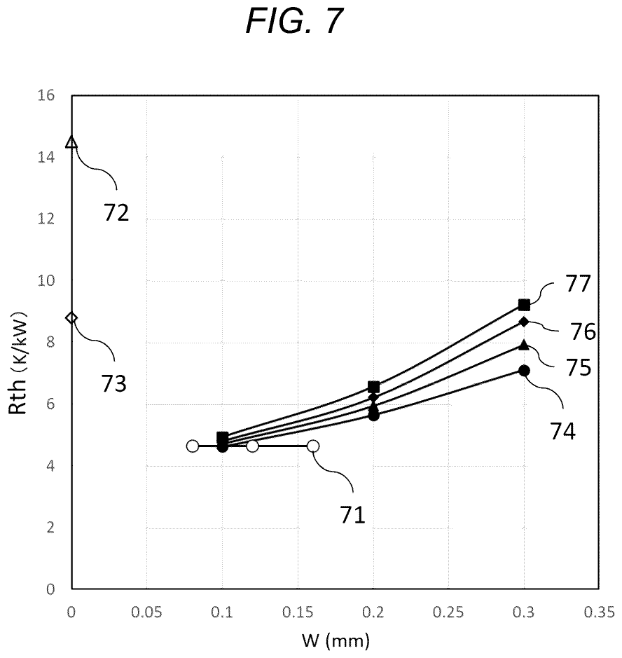

FIG. 7 is a comparison diagram of the thermal resistance of thermal conduction analysis results according to the first embodiment. FIG. 7 shows the evaluation results of the thermal resistance of the chip bonding layer 12 at the thermal resistance evaluation position 9 shown in FIG. 6a, based on a temperature difference from the surface of the semiconductor chip 1 to the lower surface of the first metal layer 3 at the center portion of the semiconductor chip 1. In FIG. 7, the thermal resistance Rth (K/kW) between chip electrodes (between the semiconductor chip 1 and the first metal layer 3) is shown on the ordinate and the width W (mm) of the trench 8 is shown on the abscissa. FIG. 7 shows the analysis results of the present invention (71) and Comparative Examples 1 to 6.

In Comparative Example 1 (72) in the graph, the chip bonding layer 12 was a solder bonding layer (thickness: 0.1 mm) without trenches. In Comparative Example 2 (73), the chip bonding layer 12 was a sinter bonding layer (thickness: 0.2 mm, thermal conductivity: 100 W/mK) without trenches. Comparative Examples having trenches uniform both in width and depth were Comparative Examples 3 to 6. In Comparative Example 3 (74), the trenches had a depth of 0.08 mm. In Comparative Example 4 (75), the trenches had a depth of 0.12 mm. In Comparative Example 5 (76), the trenches had a depth of 0.16 mm. In Comparative Example 6 (77), the trenches had a depth of 0.20 mm. From the results, it has been found that the present invention (71) makes it possible to reduce the thermal resistance between chip electrodes.

### Second Embodiment

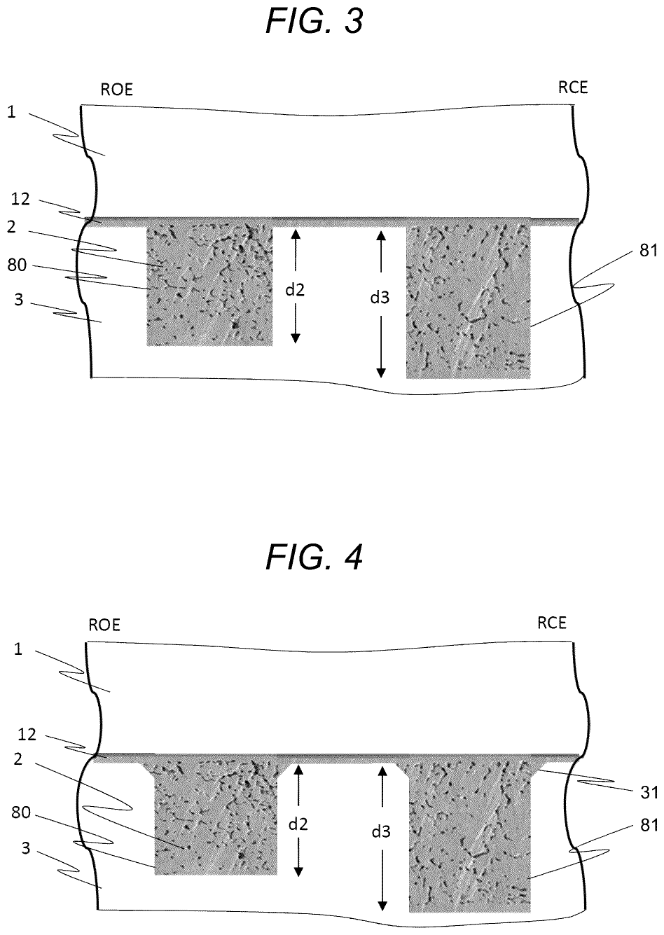

FIG. 4 is a schematic cross-sectional view showing a second embodiment by using an enlarged view of the portion D of FIG. 2b. In the second embodiment, an inclined surface 31 is placed in the trenches 80 and 81 on the side vicinity of the semiconductor chip 1.

According to the second embodiment, the bonding paste of the bonding layers 2 and 12 during manufacture can be released more easily. In addition, a stress concentration before and after the heating step can be suppressed. Further, the semiconductor chip 1 can be prevented from cracking. The method of forming the trenches 8 is preferably cutting processing using, for example, a diamond blade saw (Dual type). In this case, V-shaped trenches are formed first, followed by processing them into deeper trenches to form the trenches 80 and 81 having an inclined surface 31 on the vicinity side of the semiconductor chip 1. A sintered film is formed in the cutting mark formed on the side wall of the trenches 80 and 81 and thus, an anchoring effect can be achieved.

### Third Embodiment

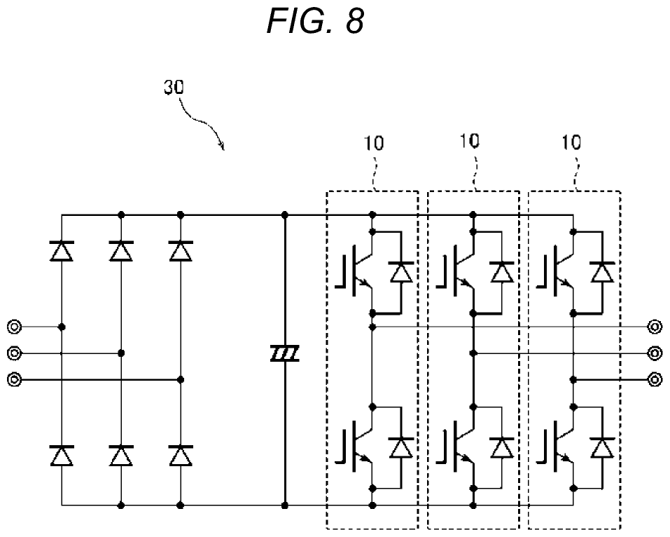

FIG. 8 is a circuit diagram showing an embodiment of an electric power conversion device 30 using the semiconductor device 10 of the first embodiment or second embodiment. The electric power conversion device 30 has a plurality of the semiconductor devices 10 and waveform signals different in timing are input into at least two gates of the semiconductor devices. The semiconductor device 10 includes, in this example, two IGBT power transistors. In the circuit in this example, an inverter device is shown, but the semiconductor device can also be applied to motors and another electric power conversion device 30 as well as the inverter device. The electric power conversion device 30 such as inverter device and motor can be incorporated in high-speed vehicles or electric vehicles as a power source thereof. By using the semiconductor device 10 of the first embodiment and second embodiment for the electric power conversion device 30, the thermal resistance of a sintered metal bonding portion can be reduced to cope with an increase in chip size and layer thinning of the semiconductor chip 1, making it possible to provide the electric power conversion device 30 having an improved rated current and to secure long-term reliability.

The invention made by the present inventors has been described specifically based on examples, but the present invention is not limited to the aforesaid embodiments and examples. It is needless to say that the invention may be changed in various ways.

### Reference Signs List

1: semiconductor chip
2: chip bonding layer (sintered metal layer)
3: first metal layer (wiring layer)
4: insulation layer
5: second metal layer
6: base bonding layer
7: base
8, 80, 81, 82, 83, 84, 85, 86: trench
9: thermal resistance evaluation position
10: semiconductor device
11: substrate
12: thin bonding layer
30: electric power conversion device
31: inclined surface

1. A semiconductor device, comprising:
a wiring layer,
a semiconductor chip, and
a sintered metal layer that bonds the semiconductor chip to the wiring layer, wherein:
the wiring layer has a trench extending from a semiconductor chip mounting region in which the semiconductor chip is mounted to an outside of the semiconductor chip mounting region,
the trench has, in the semiconductor chip mounting region, the sintered metal layer formed in the trench and on an outside of an upper end of the trench,
the trench also has the sintered metal layer in the trench formed on the outside of the semiconductor chip mounting region, and
the trench is different in depth between a vicinity of a center of the semiconductor chip mounting region and a vicinity of an end portion of the semiconductor chip mounting region.

2. The semiconductor device according to claim 1, wherein:
a depth of the trench different between the vicinity of the center of the semiconductor chip mounting region and the vicinity of the end portion of the semiconductor chip mounting region is deeper in the vicinity of the center of the semiconductor chip mounting region and is shallower in the vicinity of the end portion of the semiconductor chip mounting region.

3. The semiconductor device according to claim 2, wherein:
a width of the trench different between the vicinity of the center of the semiconductor chip mounting region and the vicinity of the end portion of the semiconductor chip mounting region is narrower in the vicinity of the center of the semiconductor chip mounting region and is wider in the vicinity of the end portion of the semiconductor chip mounting region.

4. The semiconductor device according to claim 1, wherein:
the trench has an inclined surface at an upper end thereof in the vicinity of the semiconductor chip.

5. The semiconductor device according to claim 1, wherein:
the trench includes a plurality of trenches,
the plurality of trenches extends in parallel to each other in a first direction, and
each of the plurality of trenches extends in a second direction intersecting the first direction.

6. The semiconductor device according to claim 5, wherein:
in the first direction, the depth of each of the plurality of trenches is deepest in the vicinity of the center and the depth gradually decreases from the vicinity of the center to the vicinity of the end portion.

7. The semiconductor device according to claim 6, wherein:
in the second direction, the depth of each of the plurality of trenches is deepest in the vicinity of the center and the depth gradually decreases from the vicinity of the center to the outside of the semiconductor chip mounting region.

8. The semiconductor device according to claim 7, wherein:
the plurality of trenches has the same width in the first direction.

9. The semiconductor device according to claim 7, wherein:
with regards to the width of each of the plurality of trenches, the width in the vicinity of the center is the narrowest and the width gradually increases from the vicinity of the center to the vicinity of the end portion.

10. The semiconductor device according to claim 7, wherein:
each of the plurality of trenches has, at an upper end thereof, an inclined surface in the vicinity of the semiconductor chip.

11. An electric power conversion device, comprising the semiconductor device as claimed in claim 1, wherein:
the semiconductor chip is an IGBT or MOSFET power transistor or a diode.
